(19) United States
(12) Patent Application Publication
(10) Pub. No.: US 2003/0011346 A1
(43) Pub. Date: Jan. 16, 2003

(54) Circuit arrangement comprising a chain of capacitors

(76) Inventors: Bernd Staib, Sygenstein (DE); Michael Kammerer, Heidenheim (DE)

Correspondence Address: Schiff Hardin & Waite, Patent Department, 6600 Sears Tower, Chicago, IL, 60606-6473, US

(21) Appl. No.: 10/203,768

(22) PCT Filed: Jan. 15, 2001
(86) PCT No.: PCT/DE01/00135

(30) Foreign Application Priority Data
Feb. 18, 2000 (DE) 100 07 417.0

(51) Int. Cl. H02J 1/00

(52) U.S. Cl. 320/166

(57) ABSTRACT

A circuit arrangement comprises a chain (1) composed of double layer capacitors (2). Modules (3) whose impedance lowers when the voltage across one of the double layer capacitors (2) exceeds a prescribed value are connected parallel to the double layer capacitors (2). As a result thereof, over-voltages at the double layer capacitors (2) are effectively suppressed.

The invention is directed to a circuit arrangement having a plurality of capacitors connected in series.

Double layer capacitors—often also called super capacitors or ultra capacitors or ultracaps—enable a new kind of electrochemical energy storage. They lie between large aluminum electrolytic capacitors and smaller accumulators in view of the energy density and the access time to the energy content. The energy storage in accumulators ensues with the assistance of reversible chemical reactions. Capacitors, in contrast, exploit the polarization of a dielectric in the electrical field for energy storage. In contrast, double layer capacitors have no dielectric. They store the electrical energy by charge displacement at the boundary surface between an electrode and an electrolyte.

The underlying effect is also referred to as Helmholtz effect. This effect occurs when a voltage is applied between two carbon electrodes immersed into an electrolyte. A continuous current thereby only flows when the voltage applied to the carbon electrodes exceeds a certain decomposition voltage. At the same time, a development of gas occurs as a result of a chemical reaction at the surface of the carbon electrodes. When, however, the voltage applied to the carbon electrodes remain [sic] below this decomposition voltage, the carbon electrodes behave like the electrodes of a capacitor. Upon application of the voltage, ions from the electrolyte deposit at the boundary surface to the carbon electrode, and the carbon electrodes correspondingly charge positively or negatively. The energy to be stored is thereby dependent on the available surface of the carbon electrode, on the size of the ions and on the height of the decomposition voltage.

By employing carbon electrodes composed of activated carbon and electrolyte having a decomposition voltage of 3 Volts, capacitors having an extremely high energy density (2 Wh/kg) have been successfully developed. Although the power output of these capacitors is higher than the power output of accumulators, it is clearly lower than the power output of traditional capacitors. As a result of various measure [sic], however, the voltage multipliers in the carbon electrodes were capable of being clearly lowered and a high power density of above 1000 W/kg was able to be achieved.

The allowable operating voltage of double layer capacitors, however, remains limited to a few Volts. Since the operating voltage are [sic] significantly higher in most applications, a plurality of double layer capacitors must generally be connected in series to form a module. Due to different values of the individual capacitors as well as due to different self-discharge behavior, however, the total voltage that is applied is not uniformly divided onto the individual double layer capacitors. As a result thereof, over-voltages that lead to the destruction of the double layer capacitor can occur at individual double layer capacitors.

The invention is therefore based on the object of creating a circuit arrangement with a plurality of capacitors connected in series wherein the occurrence of over-voltages is suppressed in an effective way.

This object is achieved in that the voltages at the capacitors are set by impedances connected parallel to the capacitors, whereby the sizes of the impedances are controlled with the assistance of control means dependent on the voltages at the capacitors.

The circuit arrangement of the invention comprises impedances connected parallel to the capacitors. Since the size of these impedances is variable, the over-voltages adjacent at the capacitors can be effectively suppressed by lowering the value of the impedance. It is thereby especially advantageous that the impedances adapt to the respective operating condition of the circuit arrangement.

A preferred embodiment of the invention involves a chain of double layer capacitors to which a respective control means is allocated. Module that can be joined to one another in an arbitrary number can be formed of the double layer capacitor and the allocated control means. The voltage adjacent at the double layer capacitor is thereby limited to allowable values in an effective way, so that no harmful over-voltages occur at the individual double layer capacitor.

In another preferred embodiment of the invention, the control means comprises a two-point regulation that switches the impedances back and forth between two prescribed values. Expediently, the two-point regulation is accomplished with the assistance of a threshold switch that lowers the value of the impedance given voltages at the double layer capacitor above a prescribed threshold voltage. Such a circuit arrangement can be constructed with simple means and is nonetheless suited for attenuating over-voltages that occur at the double layer capacitors.

An exemplary embodiment of the invention is explained in detail below on the basis of the attached drawing. Shown are:

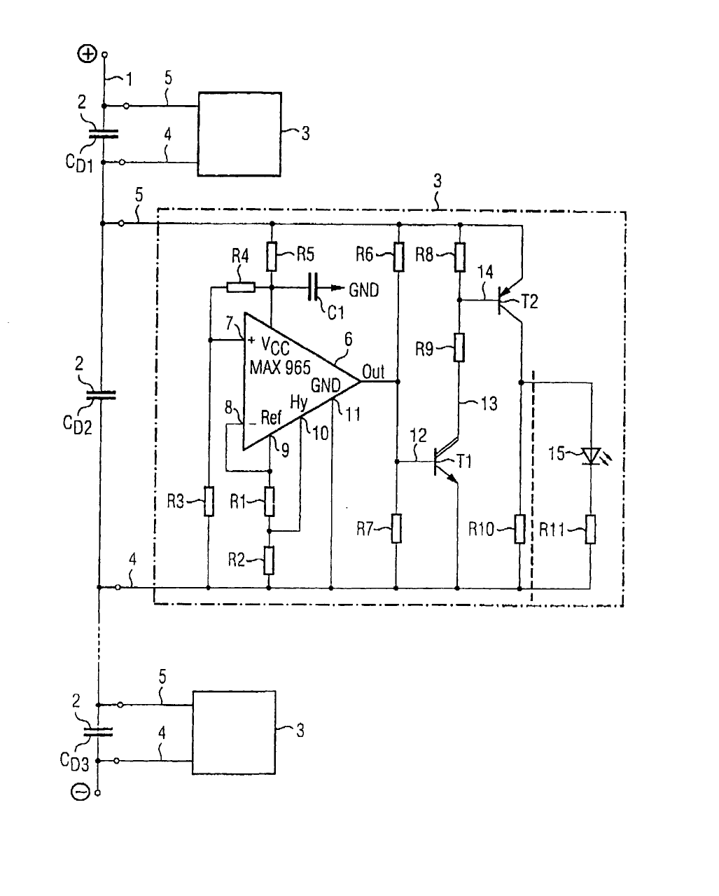

FIG. 1 a circuit diagram of a circuit arrangement according to the invention.

The circuit arrangement shown in FIG. 1 comprises a chain 1 of double layer capacitors 2 that are also referenced C_{D1} through C_{Dn} in FIG. 1. Modules 3 are connected parallel to the double layer capacitors 2, the middle module thereof being shown in detail in FIG. 1.

The module 3 is connected to the chain 1 via a ground line 4 and a voltage line 5. In this context, the term “ground line” is not intended to mean that the ground line 4 lies at a defined potential. On the contrary, the potential of the ground line 4 can float freely dependent on the voltage applied to the double layer capacitor C_{D2}. The term “ground line” is merely intended to express that the ground line 4 has the function of a ground within the module 3. The same is true of the voltage line 5.

The central part of the module 3 is the threshold switch 6. Given the exemplary embodiment shown in FIG. 1, this is a matter of a threshold switch having the designation MAX965 of the Maxim company. The threshold switch 6 is connected to the voltage line 5 via a low-pass filter formed of a resistor R5 and a capacitor C1. The low-pass filter formed by the resistor R5 and the capacitor C1 serves for the stabilization of the voltage supply of the threshold switch 6. The low-pass filter is followed by a voltage divider composed of the resistors R4 and R3 via which the voltage dropping off at the double layer capacitor C_{D2} is applied to a non-inverting input 7 of the threshold switch 6. An inverting input 8 of the threshold switch 6 is charged with a voltage from the reference output 9 of the threshold switch 6. The reference output 9 also supplies a voltage divider composed of the resistors R1 and R2 at which a voltage for a hysteresis input 10 is taken. The hysteresis of the threshold switch 6 can be set by means of the voltage adjacent at the hysteresis input 10. Finally, the threshold switch 6 also has a ground input 11 that is connected to the ground line 4.

When the voltage at the non-inverting input 7 exceeds the voltage at the inverting input 8, an output 12 of the threshold switch 6 becomes low-impedance and acts as a current sink. Conversely, the output 12 of the threshold switch 6 becomes high-impedance when the voltage at the non-inverting input 7 falls below the voltage at the inverting input 8.

A pull-up resistor R6 us provided in order to use the switching behavior of the threshold switch 6 for generating a voltage signal. As a result thereof, a voltage essentially corresponding to the voltage on the voltage line 5 is adjacent at a following Darlington circuit 1 [sic] of NPN transistors when the threshold switch 6 is high-impedance. Conversely, a voltage corresponding to the voltage on the ground line 4 lies at the input 12 of the Darlington circuit T1 [sic] when the output 11 of the threshold switch 6 is low-impedance.

However, the output 11 of the threshold switch 6 can also become high-impedance even if it were basically to be switched low-impedance due to the voltages pending at the non-inverting input 7 and inverting input 8. This is the case when the operating voltage of the threshold switch 6, i.e. the voltage between ground line 4 and voltage line 5, falls below an allowable, lower limit value. In this case, the resistor R7 is provided between the input 12 of the Darlington circuit D1 [sic] and the ground line 4. in this case, the input 12 of the Darlington circuit T1 is pulled onto the potential of the ground line 4 and a drive of the Darlington circuit T1 is prevented.

A collector terminal 13 of the Darlington circuit T1 is connected to the base of a PNP transistor T2 via a voltage divider composed of a resistor R8 and a resistor R9. Accordingly, the transistor T2 opens when the Darlington circuit T1 is through-connected. Finally, a low-impedance elimination resistor R10 is enabled by the opening of the transistor T2, the voltage adjacent at the double layer capacitor C_{D2} being thereby dismantled.

When the voltage at the double layer capacitor C_{D2} exceeds the pre-set value, the module 3 assumes a value of impedance that essentially corresponds to equal [sic] the ohmic impedance of the elimination resistor R10.

When, in contrast, the voltage at the double layer capacitor C_{D2} lies below the pre-set value, the module 3 exhibits an impedance with an ohmic resistance that is defined above all by the resistors R3 through R7.

In order to indicate the occurrence of an over-voltage at the double layer capacitor C_{D2}, a light-emitting diode 15 can be present parallel to the elimination resistor R10. Finally, a drop resistor R11 is provided for limiting the current across the light-emitting diode 15.

The voltage occurring at the at the [sic] double layer capacitors 2 is effectively limited by the modules 3. One therefore need not fear that over-voltages that lie above the allowable limit value can occur at the double layer capacitors. As a result thereof, it is possible to construct chains that comprises an overall nominal voltage of several 100 V.

1. Circuit arrangement having a plurality of capacitors (2) connected in series, characterized in that the voltages at the capacitors (2) are set by impedances (R3-R7, R10) connected parallel to the capacitors (2), whereby the sizes of the impedances (R3-R7, R19) are controlled with the assistance of control means (6, T1, T2) dependent on the voltages at the capacitors (2).

2. Circuit arrangement according to claim 1, characterized in that the capacitors are double layer capacitors (2).

3. Circuit arrangement according to claim 1 and 2, characterized in that the control means are respectively formed by control devices (6, T1, T2) allocated to a capacitor (2).

4. Circuit arrangement according to claim 3, characterized in that the control device (6, T1, T2) comprises a two-point regulation.

5. Circuit arrangement according to claim 4, characterized in that the control device comprises a threshold switch (6).

6. Circuit arrangement according to claim 5, characterized in that the threshold switch (6) employs the voltage dropping off at the allocated capacitor (2) as operating voltage.

7. Circuit arrangement according to claim 5 or 6, characterized in that the threshold switch (6) itself generates the threshold voltage employed as switching threshold.

8. Circuit arrangement according to one of the claims 5 through 7, characterized in that the threshold switch (6) controls switching transistors (T1, T2) that set the impedance (R3-R7, R10) dependent on the voltage at the allocated capacitor.
